(19) United States
(12) Patent Application Publication
(10) Pub. No.: US 2018/0330957 A1
(43) Pub. Date: Nov. 15, 2018

(54) WORKPIECE PROCESSING METHOD

(71) Applicant: DISCO CORPORATION, Tokyo (JP)

(72) Inventors: Frank Wei, Tokyo (JP); Tomotaka Tabuchi, Tokyo (JP); Hideyuki Sandoh, Tokyo (JP)

(21) Appl. No.: 15/974,223

(22) Filed: May 8, 2018

(30) Foreign Application Priority Data
May 10, 2017 (JP) 2017-094115

(51) Int. Cl. H01L 21/3065; H01L 21/308; H01L 21/02; H01L 21/683

(52) U.S. Cl. CPC H01L 21/3065; H01L 21/6836; H01L 21/02068; H01L 21/308

(57) ABSTRACT

Disclosed herein is a workpiece processing method including a mask preparing step of preparing a mask that covers devices on a front surface of a workpiece and exposes streets, a plasma etching step of repeating an operation of supplying plasmatized SF₆ through the mask to the workpiece accompanied by a holding member disposed on a back surface thereof, to form grooves, then supplying plasmatized C₄F₈ to the workpiece through the mask to deposit a coating on the workpiece, and thereafter supplying plasmatized SF₆ to the workpiece through the mask to remove the coating present at bottoms of the grooves, thereby etching the groove bottoms, and a foreign matter removing step of cleaning the workpiece with a cleaning liquid, after the plasma etching step is conducted, to remove the coating produced in the plasma etching step.

### BACKGROUND OF THE INVENTION

### Field of the Invention

The present invention relates to a processing method for a workpiece which has a front surface formed with a device in each of regions partitioned by a plurality of intersecting streets, the device being provided with projecting electrodes.

### Description of the Related Art

Plasma dicing has been known as a method for dividing a substrate or wafer formed from silicon (see, for example, Japanese Patent Laid-Open No. 2006-114825 and Japanese Patent No. 4090492). On the other hand, a wafer provided with devices for flip-chip mounting, a wafer provided with devices composed of wafer level chip size package (WLCSP) or the like is formed with projecting electrodes each of which is, for example, in a spherical shape, in a pillar shape, or in the shape of a pillar with a spherical upper end portion.

### SUMMARY OF THE INVENTION

However, particularly when the plasma dicing using the Bosch method described in Japanese Patent No. 4090492 is applied to a wafer formed with projecting electrodes, foreign matter (coating or film) produced would be deposited on the projecting electrodes. When the device with the foreign matter adhering to the projecting electrode is mounted, defective mounting or breaking of wire may be generated, or corrosion of the projecting electrode due to the foreign matter may be generated with the result of breaking.

Accordingly, it is an object of the present invention to provide a processing method by which it is possible to restrain defective mounting of a device or breaking after the processing, such as breaking of wire.

In accordance with an aspect of the present invention, there is provided a workpiece processing method of processing a workpiece which has a front surface formed with a device in each of regions partitioned by a plurality of intersecting streets, the device being provided with projecting electrodes. The method includes a mask preparing step of preparing a mask that covers the devices on the front surface of the workpiece and exposes the streets, a plasma etching step of repeating an operation of supplying plasmatized SF₆ through the mask to the workpiece in which the devices on the front surface are covered with the mask and which is accompanied by a holding member disposed on a back surface thereof, to form grooves, then supplying plasmatized C₄F₈ to the workpiece through the mask to deposit a coating on the workpiece, and thereafter supplying plasmatized SF₆ to the workpiece through the mask to remove the coating present at bottoms of the grooves, thereby etching the groove bottoms, and a foreign matter removing step of cleaning the workpiece with a cleaning liquid, after the plasma etching step is conducted, to remove the coating produced in the plasma etching step.

Preferably, the processing method further includes a holding member disposing step of disposing the holding member on the back surface of the workpiece, before conducting the plasma etching step. Preferably, the foreign matter removing step is carried out by immersing the workpiece in the cleaning liquid.

Preferably, the holding member includes a tape including a base material layer and a glue layer disposed on the base material layer, and an annular frame to which an outer peripheral edge of the tape is attached, and, in the foreign matter removing step, the workpiece is immersed in the cleaning liquid together with the tape adhered to the back surface of the workpiece and the annular frame. Preferably, the foreign matter removing step is carried out by heating the cleaning liquid to a temperature of not lower than normal temperature and applying ultrasonic vibration to the cleaning liquid.

The processing method according to the present invention has an effect to make it possible to restrain defective mounting of a device and breaking after the processing, such as breaking of wire.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of an example of a workpiece to be processed by a processing method according to a first embodiment;

FIG. 2 is a plan view depicting the part II of FIG. 1 in an enlarged form;

FIG. 3 is a sectional view of a projecting electrode and the like of the workpiece depicted in FIG. 2;

FIG. 4 is a flow chart depicting the flow of the processing method according to the first embodiment;

FIG. 5 is a perspective view of a workpiece after a holding member disposing step of the processing method depicted in FIG. 4;

FIG. 6 is a sectional view of a part of the workpiece and an adhesive tape depicted in FIG. 5;

FIG. 7 is a partly sectional side view depicting a mask preparing step of the processing method depicted in FIG. 4;

FIG. 8 is a sectional view depicting the configuration of an etching apparatus used in a plasma etching step of the processing method depicted in FIG. 4;

FIG. 9 is a sectional view of a major part of the workpiece after the plasma etching step of the processing method depicted in FIG. 4;

FIG. 10 is a sectional view depicting a foreign matter removing step of the processing method depicted in FIG. 4;

FIG. 11 is a flow chart depicting the flow of a processing method according to a second embodiment; and

FIG. 12 is a flow chart depicting the flow of a processing method according to a third embodiment.

### DETAILED DESCRIPTION OF THE PREFERRED EMBODIMENTS

Modes (embodiments) for carrying out the present invention will be described in detail below, referring to the drawings. The present invention is not to be limited by the contents of the following description. In addition, the constituent elements described below include those which can be easily conceived by persons skilled in the art and substantial equivalents thereof. Further, the configurations described below can be combined, as required. Besides, various omissions, replacements, and modifications can be made without departing from the spirit or scope of the present invention.

### First Embodiment

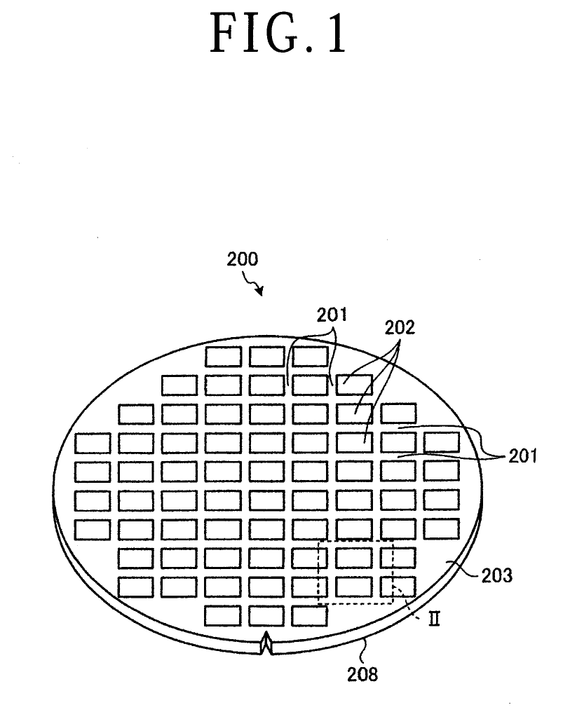

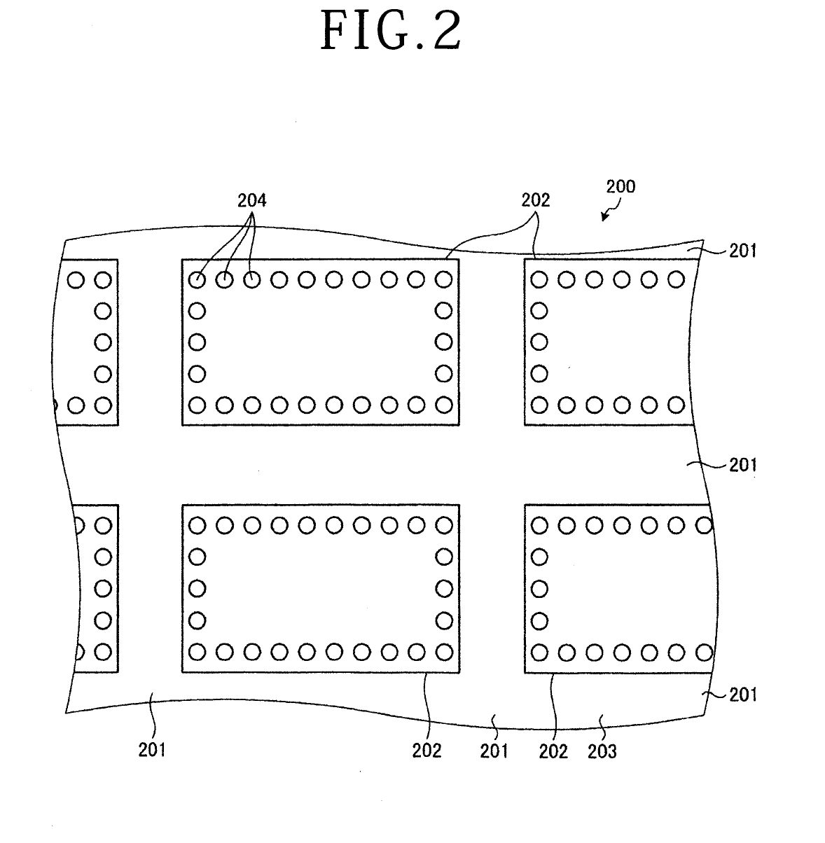

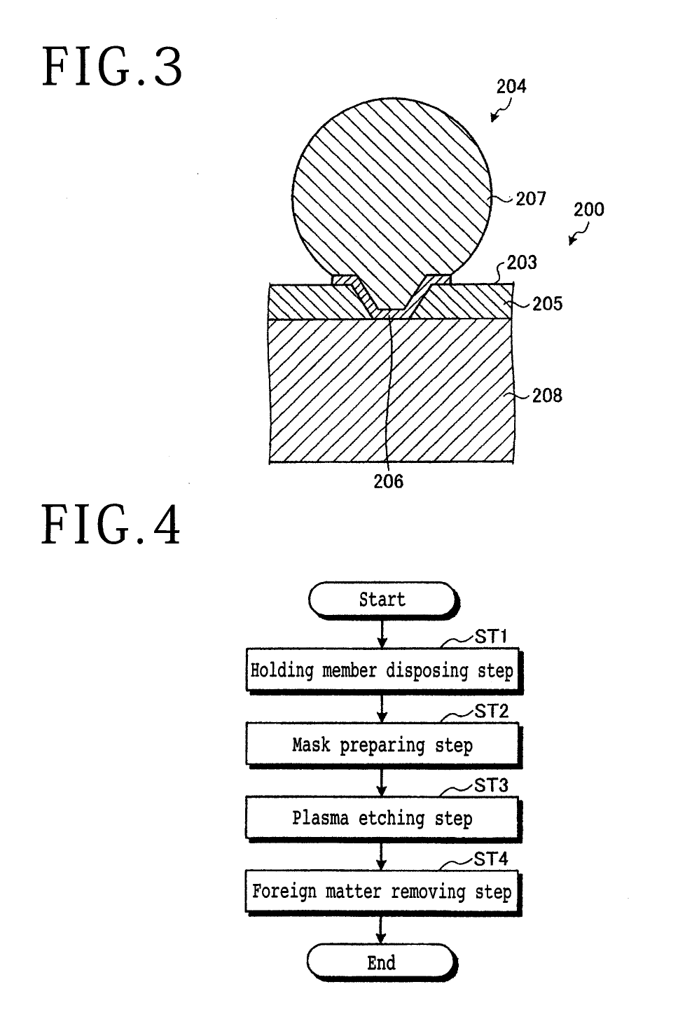

A processing method according to a first embodiment of the present invention will be described referring to the drawings. FIG. 1 is a perspective view of an example of a workpiece to be processed by the processing method according to the first embodiment. FIG. 2 is a plan view depicting the part II of FIG. 1 in an enlarged form. FIG. 3 is a sectional view of a projecting electrode and the like of the workpiece depicted in FIG. 2.

The processing method according to the first embodiment is a processing method for a workpiece 200 depicted in FIG. 1. In the first embodiment, the workpiece 200 is a disk-shaped semiconductor wafer or optical device wafer having a substrate formed of silicon, sapphire, gallium arsenide or the like. As depicted in FIG. 1, the workpiece 200 has a front surface 203 formed with a device 202 in each of regions partitioned by a plurality of intersecting streets 201.

As depicted in FIG. 2, the device 202 is provided with a plurality of projecting electrodes 204. In addition, as illustrated in FIG. 3, a passivation layer 205 is stacked on a surface of the substrate of the workpiece 200, exclusive of the projecting electrode 204. The passivation layer 205 is a passivation film. The passivation film is used as a mask in forming the projecting electrodes 204. Besides, the passivation film, by being stacked on the surface of the substrate, protects circuits of the devices 202 from external environments, and protects the circuits of the devices 202 physically and chemically. The passivation film is formed, for example, from a photosensitive polyimide. The passivation film is a film which is difficult to subject plasma etching. In the first embodiment, the passivation layer 205 is formed on the surface of the substrate of the workpiece 200, exclusive of the projecting electrodes 204. In the present invention, however, the passivation layer may be formed on the whole surfaces of the devices 202 such as to play the role of passivation for protecting the surfaces of the devices 202. In addition, in the present invention, the passivation film formed of a photosensitive polyimide may be formed only at positions corresponding to the projecting electrodes 204; in this case, the upper surfaces of the devices 202 are protected by a passivation film formed of a material different from the polyimide for the mask.

The projecting electrodes 204 are provided on the devices 202. In the first embodiment, as depicted in FIG. 3, the projecting electrode 204 includes a soldered electrode 206 on the device 202, and a spherical bump 207 provided on the soldered electrode 206. In the first embodiment, the soldered electrode 206 is an underbump metal (UBM) formed of nickel or a nickel alloy. In the first embodiment, the bump 207 is formed of a so-called lead-free solder composed of a Sn—Ag alloy. In the first embodiment, the device 202 is a so-called WLCSP provided with the projecting electrodes 204. Note that while the projecting electrode 204 has the spherical bump 207 in the first embodiment, the projecting electrode may be formed in a pillar shape in the present invention.

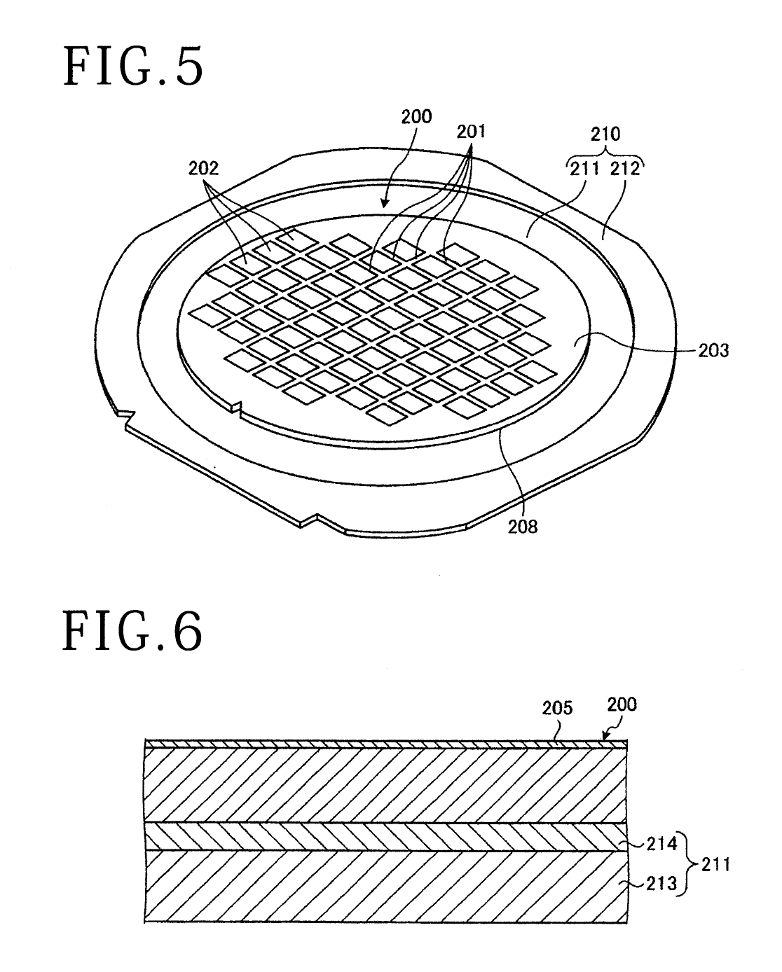

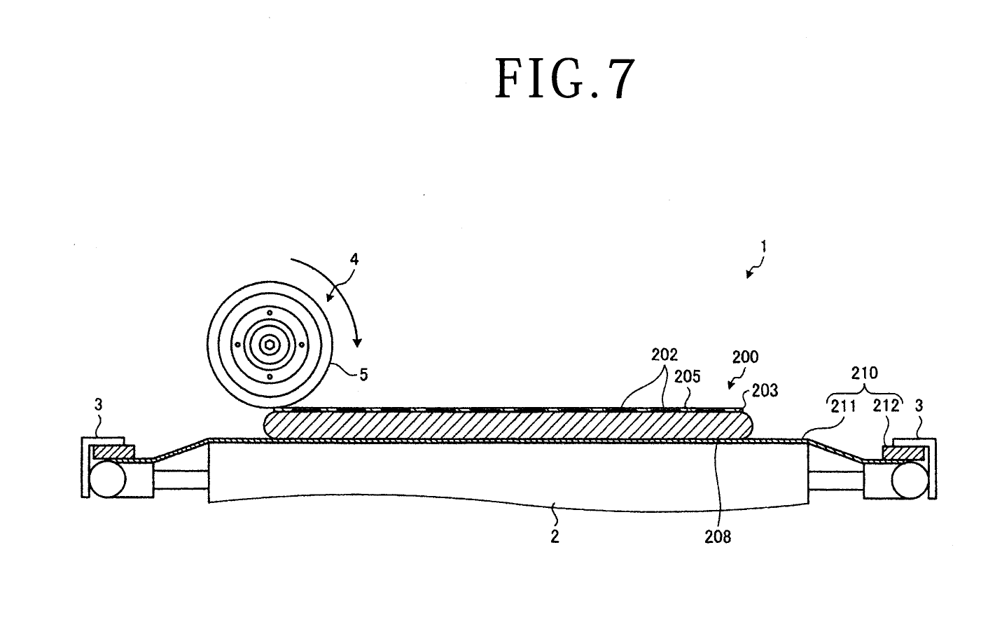

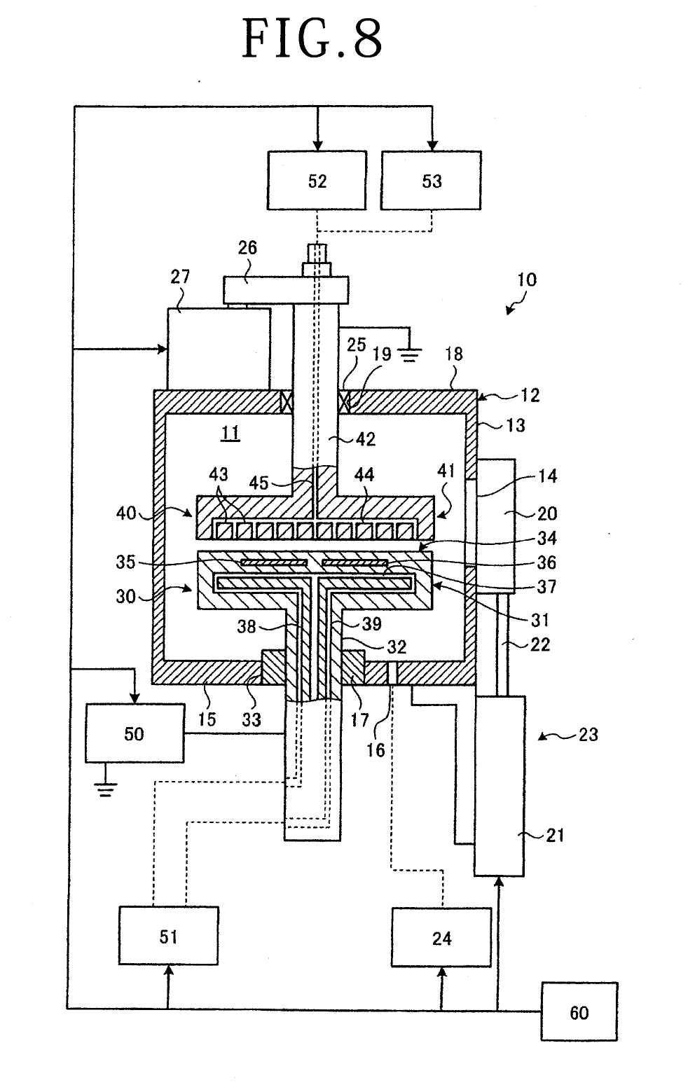

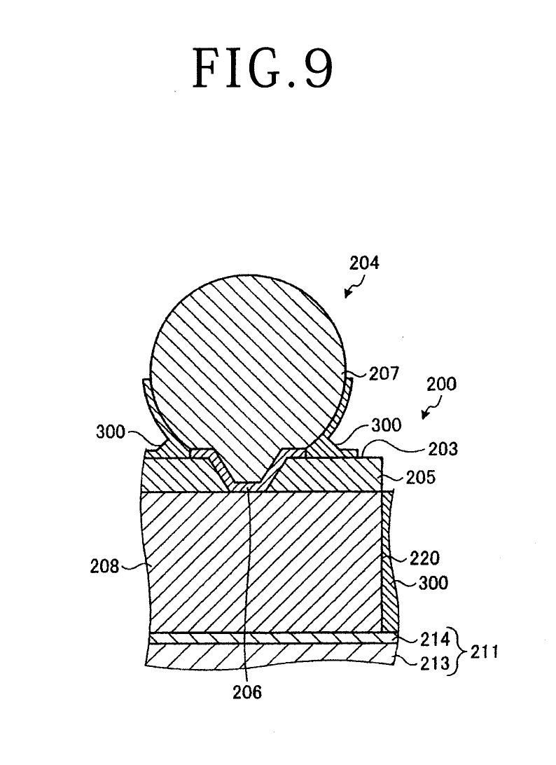

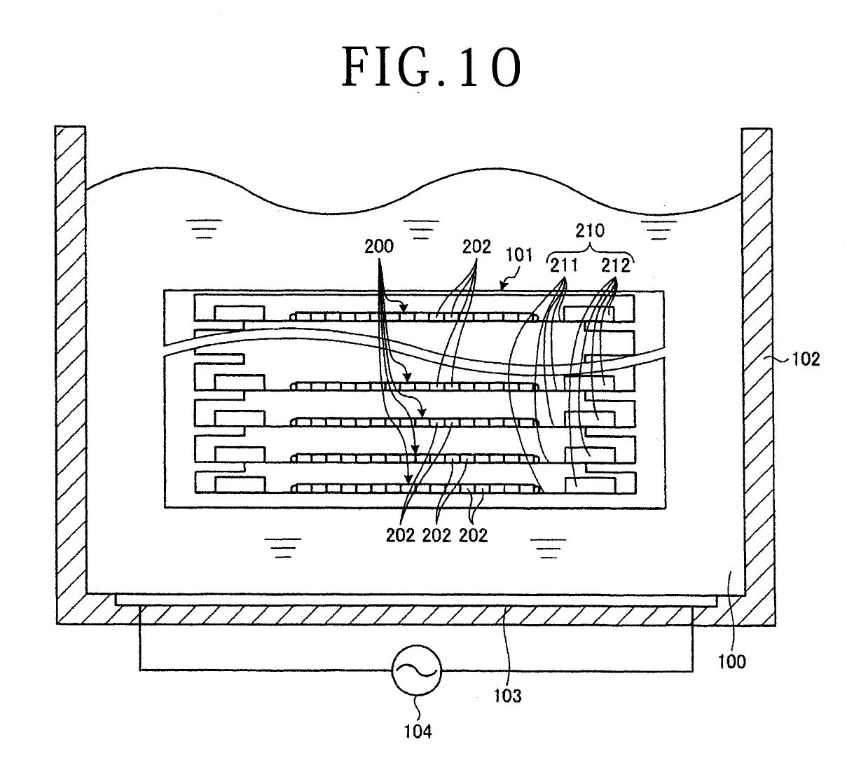

FIG. 4 is a flow chart depicting the flow of the processing method according to the first embodiment. FIG. 5 is a perspective view of a workpiece after a holding member disposing step of the processing method depicted in FIG. 4. FIG. 6 is a sectional view of part of the workpiece and an adhesive tape depicted in FIG. 5. FIG. 7 is a side view depicting a mask preparing step of the processing method depicted in FIG. 4. FIG. 8 is a sectional view depicting the configuration of an etching apparatus used for a plasma etching step of the processing method depicted in FIG. 4. FIG. 9 is a sectional view of a major part of the workpiece after the plasma etching step of the processing method depicted in FIG. 4. FIG. 10 is a figure for explaining a foreign matter removing step of the processing method depicted in FIG. 4.

The processing method according to the first embodiment is a method of cutting the workpiece 200 along the streets 201, to thereby divide the workpiece 200 into individual devices 202. As depicted in FIG. 4, the processing method includes a holding member disposing step ST1, a mask preparing step ST2, a plasma etching step ST3, and a foreign matter removing step ST4.

The holding member disposing step ST1 is a step of disposing a holding member 210 on a back surface 208 on the back side of the front surface 203 of the workpiece 200, before carrying out the plasma etching step ST3. In the first embodiment, as depicted in FIG. 5, the holding member 210 includes an adhesive tape 211 which is a tape, and an annular frame 212 to which an outer peripheral edge of the adhesive tape 211 is attached. As depicted in FIG. 6, the adhesive tape 211 includes a base material layer 213 formed of a synthetic resin such as polyethylene terephthalate (PET), polyolefin (PO), or polyvinyl chloride (PVC), and a glue layer 214 which is formed of an acrylic or rubber-based resin, is disposed on the base material layer 213, and is adhered to the back surface 208 of the workpiece 200. In the holding member disposing step ST1, as depicted in FIG. 5, the back surface 208 of the workpiece 200 is adhered to the adhesive tape 211, which is accompanied by the annular frame 212 attached to an outer peripheral portion thereof. Note that in FIG. 6, the bumps 207, that is, the projecting electrodes 204, are omitted.

Note that in the present invention, in the holding member disposing step ST1, a protective tape which is a holding member formed of a synthetic resin such as PET, PO, or PVC having the same size as that of the workpiece 200 may be adhered to the back surface 208 of the workpiece 200. Besides, in the present invention, in the holding member disposing step ST1, a glass plate, a silicon wafer, or a ceramic plate may be adhered to the back surface 208 of the workpiece 200, as a holding member. The processing method proceeds to the mask preparing step ST2.

The mask preparing step ST2 is a step of preparing a mask which covers the devices 202 on the front surface 203 of the workpiece 200 while exposing the streets 201. In the first embodiment, in the mask preparing step ST2, as depicted in FIG. 7, the workpiece 200 is suction held on a chuck table 2 of a cutting apparatus 1 through the adhesive tape 211, and the annular frame 212 is clamped by clamp portions 3. In the mask preparing step ST2, while moving a cutting unit 4 of the cutting apparatus 1 relative to the workpiece 200 along the street 201, a cutting blade 5 is made to cut into the passivation layer 205 on the street 201, to remove the passivation layer 205 present on the street 201, thereby exposing the substrate in the area of the street 201. In the first embodiment, the passivation layer 205 is removed at the parts on the streets 201, thereby being formed into a mask.

In the first embodiment, cutting processing is applied to the streets 201 to expose the substrate in the areas of the streets 201 in the mask preparing step ST2, but this is not limitative of the present invention; the substrate in the areas of the streets 201 may be exposed by a method wherein a laser light is applied to the streets 201 to perform ablation, thereby to remove the passivation layer 205 on the streets 201. Besides, in the present invention, in the case where the passivation layer 205 on the streets 201 is removed in a preceding step, the workpiece 200 with the holding member 210 attached thereto may be prepared, to prepare the aforementioned mask, in the mask preparing step ST2. The processing method proceeds to the plasma etching step ST3.

The plasma etching step ST3 is a step of repeating an operation of supplying plasmatized SF₆ to the workpiece 200 in which the devices 202 on the front surface 203 are covered with the passivation layer 205 serving as a mask and which is accompanied by the adhesive tape 211 serving as a holding member disposed on the back surface 208, through the passivation layer 205, to form the grooves 220 depicted in FIG. 9 in the streets 201, then supplying plasmatized C₄F₈ to the workpiece 200 through the passivation layer 205 to deposit a coating on the workpiece 200, and thereafter supplying plasmatized SF₆ to the workpiece 200 through the passivation layer 205 to remove the coating present at bottoms of the grooves 220, thereby etching the bottom surfaces at the bottoms of the grooves 220. In the first embodiment, in the plasma etching step ST3, the streets 201 are removed by etching, to divide the workpiece 200 into the individual devices 202.

The plasma etching step ST3 is carried out using an etching apparatus 10 illustrated in FIG. 8. The etching apparatus 10 depicted in FIG. 8 has a housing 12 that defines a hermetically sealed space 11. A side wall 13 of the housing 12 is provided with an opening 14 through which the workpiece 200 is to be carried in and out. On the outside of the opening 14, a gate 20 for opening and closing the opening 14 is disposed to be movable in the vertical direction. The gate 20 is moved in the vertical direction by a gate operating unit 23 including a cylinder 21 and a piston rod 22 that can be contracted and extended from the cylinder 21. In addition, a bottom wall 15 of the housing 12 is provided with an exhaust port 16 connected to a gas exhaust unit 24.

The etching apparatus 10 includes a lower electrode 30 and an upper electrode 40 which are oppositely disposed in the hermetically sealed space 11. The lower electrode 30 is formed from a conductive material, and includes a disk-shaped workpiece holding section 31 and a cylindrical support section 32 protruding from a central portion of a lower surface of the workpiece holding section 31. The lower electrode 30 has the support section 32 being inserted and passed through a hole 17, which is formed in the bottom wall 15 of the housing 12, and being supported in the state of being sealed to the bottom wall 15 through an insulating body 33. The lower electrode 30 is electrically connected to a high-frequency power supply 50 through the support section 32.

A suction holding member 34 (electrostatic chuck (ESC)) is provided at an upper portion of the workpiece holding section 31 of the lower electrode 30. The suction holding member 34 includes a positive electrode 35 to which a plus voltage is applied from a power supply (not depicted), and a negative electrode 36 to which a minus voltage is applied from the power supply. In using the lower electrode 30, the workpiece 200 is mounted on the suction holding member 34, a plus voltage is impressed on the positive electrode 35, and a minus voltage is impressed on the negative electrode 36, to generate an electrostatic suction force between the electrodes 35 and 36, whereby the workpiece 200 is suction held on the suction holding member 34.

In addition, a cooling passage 37 is formed under the workpiece holding section 31 of the lower electrode 30. One end of the cooling passage 37 communicates with a coolant introduction passage 38 formed in the support section 32, and the other end of the cooling passage 37 communicates with a coolant discharge passage 39 formed in the support section 32. The coolant introduction passage 38 and the coolant discharge passage 39 communicate with a coolant supply unit 51. When the coolant supply unit 51 is operated, helium gas as a coolant is circulated through the coolant introduction passage 38, the cooling passage 37, and the coolant discharge passage 39, whereby an abnormal rise in the temperature of the lower electrode 30 is prevented.

The upper electrode 40 is formed from a conductive material, and includes a disk-shaped gas jetting section 41, and a cylindrical support section 42 protruded from a central portion of an upper surface of the gas jetting section 41. The upper electrode 40 has the gas jetting section 41 disposed oppositely to the workpiece holding section 31 constituting the lower electrode 30, and has the support section 42 being inserted and passed through a hole 19, which is formed in an upper wall 18 of the housing 12, and being supported in a vertically movable manner by a seal member 25 mounted in the hole 19. An upper end portion of the support section 42 is connected to a lift drive unit 27 through an operating member 26. Note that high-frequency electric power is impressed on the upper electrode 40 from the high-frequency power supply 50.

The gas jetting section 41 of the upper electrode 40 is provided with a plurality of jet ports 43 opening in a lower surface thereof. The jet ports 43 are connected to a SF₆ gas supply unit 52 and a C₄F₈ gas supply unit 53 through a communication passage 44 formed in the gas jetting section 41 and a communication passage 45 formed in the support section 42.

The etching apparatus 10 has a control unit 60 which controls the gate operating unit 23, the gas exhaust unit 24, the high-frequency power supply 50, the coolant supply unit 51, the lift drive unit 27, the SF₆ gas supply unit 52, the C₄F₈ gas supply unit 53 and the like. The control unit 60 controls constituent elements of the etching apparatus 10, thereby causing the etching apparatus 10 to perform an operation of plasma-etching the workpiece 200. Note that the control unit 60 is a computer. The control unit 60 includes a processing apparatus having a microprocessor such as a central processing unit (CPU), a storage apparatus having a memory such as a read only memory (ROM) or a random access memory (RAM), and an input/output interface apparatus. The processing apparatus of the control unit 60 executes a processing according to a computer program stored in the storage apparatus, whereby control signals for controlling the etching apparatus 10 are output to the aforementioned constituent elements of the etching apparatus 10 through the input/output interface apparatus.

In the plasma etching step ST3, the control unit 60 operates the gate operating unit 23 to move the gate 20 downward in FIG. 8, thereby opening the opening 14 of the housing 12. Next, the workpiece 200 having undergone the mask preparing step ST2 is carried into the hermetically sealed space 11 in the housing 12 through the opening 14 by carrying-in/out means (not depicted), and the back surface 208 of the workpiece 200 is mounted on the suction holding member 34 of the workpiece holding section 31 constituting the lower electrode 30, through the adhesive tape 211. In this instance, the control unit 60 preliminarily operates the lift drive unit 27, to raise the upper electrode 40. The control unit 60 impresses electric power on the electrodes 35 and 36, whereby the workpiece 200 is suction held on the suction holding member 34.

The control unit 60 operates the gate operating unit 23 to move the gate 20 upward, thereby closing the opening 14 of the housing 12. The control unit 60 operates the lift drive unit 27 to lower the upper electrode 40, whereby the distance between the lower surface of the gas jetting section 41 constituting the upper electrode 40 and the workpiece 200 held by the workpiece holding section 31 constituting the lower electrode 30 is set to a predetermined inter-electrode distance (for example, 10 mm) suitable for a plasma etching treatment.

The control unit 60 operates the gas exhaust unit 24 to evacuate the hermetically sealed space 11 inside the housing 12, and maintains the pressure inside the hermetically sealed space 11 at 25 Pa. The control unit 60 alternately repeats an etching step of supplying plasmatized SF₆ to the workpiece 200 to form grooves 220 and a coating deposition step of supplying plasmatized C₄F₈ to the workpiece 200, after the etching step, to deposit a coating on the workpiece 200. Note that the etching step after the coating deposition step is for removing the coating present at bottoms of the grooves 220 to etch the bottom surfaces at the bottoms of the grooves 220. Thus, in the plasma etching step ST3, the workpiece 200 is subjected to plasma etching by the so-called Bosch method.

Note that in the etching step, the control unit 60 operates the SF₆ gas supply unit 52 to jet the SF₆ gas from the plurality of jet ports 43 of the upper electrode 40 toward the workpiece 200 held on the suction holding member 34 of the lower electrode 30. Then, in the state in which the SF₆ gas for generating a plasma is being supplied, the control unit 60 impresses a high-frequency electric power for generating and maintaining a plasma on the upper electrode 40 from the high-frequency power supply 50, and impresses a high-frequency electric power for drawing-in of ions on the lower electrode 30 from the high-frequency power supply 50. By this, an isotropic plasma of the SF₆ gas is generated in the space between the lower electrode 30 and the upper electrode 40, the plasma is drawn in to the workpiece 200, whereby the streets 201 exposed from the passivation layer 205 are etched, to form the grooves 220.

Besides, in the coating deposition step, the control unit 60 operates the C₄F₈ gas supply unit 53 to jet the C₄F₈ gas for plasma generation from the plurality of jet ports 43 of the upper electrode 40 toward the workpiece 200 held on the suction holding member 34. Then, in the state in which the C₄F₈ gas for plasma generation is being supplied, the control unit 60 impresses a high-frequency electric power for generating and maintaining a plasma on the upper electrode 40 from the high-frequency power supply 50, and impresses a high-frequency electric power for drawing-in of ions on the lower electrode 30 from the high-frequency power supply 50. By this, a plasma of the C₄F₈ gas is generated in the space between the lower electrode 30 and the upper electrode 40, and the plasma is drawn in to the workpiece 200, to deposit a coating on the workpiece 200.

In both the etching step and the coating deposition step, the control unit 60 controls the constituent elements of the etching apparatus 10 under the following conditions.

Pressure in hermetically sealed space 11: 25 Pa

Frequency of high-frequency electric power: 13.56 MHz

Temperature of suction holding member 34: 10° C.

Pressure of helium gas supplied to coolant supply unit 51: 2,000 Pa (gauge pressure)

In the etching step, the control unit 60 controls the constituent elements of the etching apparatus 10 under the following conditions.

Power impressed on upper electrode 40: 2,500 W

Power impressed on lower electrode 30: 150 W

Kind of gas supplied from upper electrode 40: SF₆

Flow rate of gas supplied from upper electrode 40: 400 sccm (standard cubic centimeter per minute)

Step Time: Five Seconds

In the coating deposition step, the control unit 60 controls the constituent elements of the etching apparatus 10 under the following conditions.

Power impressed on upper electrode 40: 2,500 W

Power impressed on lower electrode 30: 50 W

Kind of gas supplied from upper electrode 40: C₄F₈

Flow rate of gas supplied from upper electrode 40: 400 sccm

Step Time: Three Seconds

In the plasma etching step ST3, the control unit 60 sets the number of times the etching step and the coating deposition step are to be repeated, according to the depth of the grooves 220, in other words, according to the thickness of the workpiece 200. In the first embodiment, the control unit 60 repeats the etching step and the coating deposition step 50 times each, namely, repeats 50 cycles of the steps; in the present invention, however, the number of cycles is not limited to 50. When the plasma etching step ST3 is finished, the processing method proceeds to the foreign matter removing step ST4.

Note that in the first embodiment, the workpiece 200 having undergone the plasma etching step ST3 is in a state as depicted in FIG. 9 in which the grooves 220 penetrate the substrate and the workpiece 200 is adhered to the adhesive tape 211 in the state of being divided into the individual devices 202. On the device 202 after the plasma etching step ST3, as depicted in FIG. 9, a coating 300 formed of fluorocarbon (CₓF_{y}) which is a foreign matter produced in the plasma etching step ST3 is deposited. In the first embodiment, the coating 300 is adhering to cut surfaces of the grooves 220, the surface of the passivation layer 205 (particularly, in the vicinity of the bumps 207), and the surfaces of the bumps 207 (particularly, in the vicinity of the passivation layer 205).

The foreign matter removing step ST4 is a step of cleaning the workpiece 200 with a cleaning liquid 100 depicted in FIG. 10, after conduction of the plasma etching step ST3, to remove the coating 300 generated in the plasma etching step ST3. In the first embodiment, in the foreign matter removing step ST4, a plurality of workpieces 200 having undergone the plasma etching step ST3 are accommodated in a cassette 101 in the state of being adhered to the adhesive tape 211 and supported by the annular frame 212.

In carrying out the foreign matter removing step ST4, as depicted in FIG. 10, the cassette 101 accommodating the plurality of workpieces 200 is inserted into a cleaning tank 102 containing the cleaning liquid 100 heated to a temperature of not lower than normal temperature, and the workpiece 200 are immersed in the cleaning liquid 100 together with the adhesive tapes 211 and the annular frames 212. Besides, in the first embodiment, in the foreign matter removing step ST4, electric power from an alternate current (AC) power supply 104 is impressed on an ultrasonic vibration unit 103 provided in the cleaning tank 102 to put the cleaning liquid 100 in the cleaning tank 102 into ultrasonic vibration, thereby removing the coating 300 from the workpieces 200. Thus, in the first embodiment, in the foreign matter removing step ST4, the cleaning liquid 100 is heated to a temperature of not lower than normal temperature and ultrasonic vibration is applied, but ultrasonic vibration may not necessarily be applied in the present invention.

In addition, while the cleaning liquid 100 is heated to a temperature of 45° C. to 50° C. in the foreign matter removing step ST4 in the first embodiment, the temperature of the cleaning liquid 100 is not limited to this. Besides, in the foreign matter removing step ST4 in the first embodiment, cleaning is conducted by impressing an electric power of 200 W on the ultrasonic vibration unit 103 from the AC power supply 104 and applying ultrasonic vibration of 100 kHz to the cleaning liquid 100 for a time of 10 to 15 minutes. However, the electric power to be impressed from the AC power supply 104, the frequency of the ultrasonic vibration to be applied to the cleaning liquid 100 and the cleaning time are not limited to the just-mentioned. After the foreign matter removing step ST4 in the processing method, the workpieces 200 are taken out of the cleaning tank 102, and are subjected to natural drying.

Note that in the present invention, a liquid which does not dissolve the adhesive tapes 211 nor the annular frames 212 (particularly, a liquid which does not lower the adhesive force of the glue layer 214) is desirably used as the cleaning liquid 100. A fluorine-based cleaning liquid or a resist stripping agent ordinarily used for removing a resist which has resistance to plasma etching can be used. Specifically, HFE (hydrofluoroether) can be used as the fluorine-based cleaning liquid, and an organic solvent-based resist stripping agent can be used as the resist stripping agent.

In addition, while a so-called sheet-fed processing (or single wafer processing) wherein a plurality of workpieces 200 are cleaned by immersion in the cleaning liquid 100 together with the cassette 101 containing the workpieces 200 is conducted in the foreign matter removing step ST4 in the first embodiment, a so-called batch processing wherein the workpieces 200 are immersed one by one in the cleaning liquid 100 may be performed in the present invention.

In the processing method according to the first embodiment, the foreign matter removing step ST4 of removing the coating 300 as the foreign matter by use of the cleaning liquid 100 is conducted after the plasma etching step ST3, and, therefore, the coating 300 can be removed from the devices 202. As a result, it is possible, by the processing method according to the first embodiment, to restrain defective mounting of the device 202 and breaking after the processing, such as breaking of wire.

In addition, in the processing method according to the first embodiment, the holding member 210 is attached to the back surface 208 of the workpiece 200 in the holding member disposing step ST1. Therefore, particularly the workpiece 200 after the plasma etching step ST3 can be carried together with the holding member 210, so that the workpiece 200 can be easily carried.

Besides, in the processing method according to the first embodiment, the workpiece 200 is immersed in the cleaning liquid 100 in the foreign matter removing step ST4. By the processing method, therefore, the coating 300 deposited between the lower end of the bump 207 of the projecting electrode 204 and the front surface 203 of the workpiece 200 can be removed. Besides, in the case where the projecting electrode 204 is formed in a cylindrical shape, it is possible to remove the coating 300 deposited in a so-called undercut generated by hollowing on the electrode lower side during formation of the projecting electrode 204.

In addition, in the processing method according to the first embodiment, the holding member 210 includes the adhesive tape 211 and the annular frame 212. Therefore, particularly the workpiece 200 after the plasma etching step ST3 can be carried together with the annular frame 212, so that the workpiece 200 can be easily carried.

Besides, in the processing method according to the first embodiment, the cleaning liquid 100 is heated to a temperature of not lower than normal temperature and ultrasonic vibration is applied to the cleaning liquid 100 in the foreign matter removing step ST4. Therefore, the cleaning liquid 100 with minute vibrations applied thereto can be made to collide against the coating 300, whereby the coating 300 can be removed.

In addition, in the case where a fluorine-based cleaning liquid, particularly HFE (hydrofluoroether), is used as the cleaning liquid 100 in the processing method according to the first embodiment, the coating 300 can be removed from the devices 202, without lowering the adhesive force of the glue layer 214 of the adhesive tape 211 of any of various kinds even when the workpiece 200 is immersed in the cleaning liquid 100. As a result, in the processing method, the foreign matter removing step ST4 can be performed while preventing the workpiece 200 from dropping, so that the coating 300 can be removed without lowering the property for being carried of the workpiece 200.

Besides, in the case where a resist stripping agent, particularly an organic solvent-based resist stripping agent, is used as the cleaning liquid 100 in the processing method according to the first embodiment, the coating 300 can be removed from the devices 200, without lowering the adhesive force of the glue layer 214 of the adhesive tape 211 of a specific kind even when the workpiece 200 is immersed in the cleaning liquid 100. As a result, in the processing method, the foreign matter removing step ST4 can be conducted while preventing the workpiece 200 from dropping, and the amount of the coating 300 left on the device 202 can be suppressed without lowering the property for being carried of the workpiece 200.

### Second Embodiment

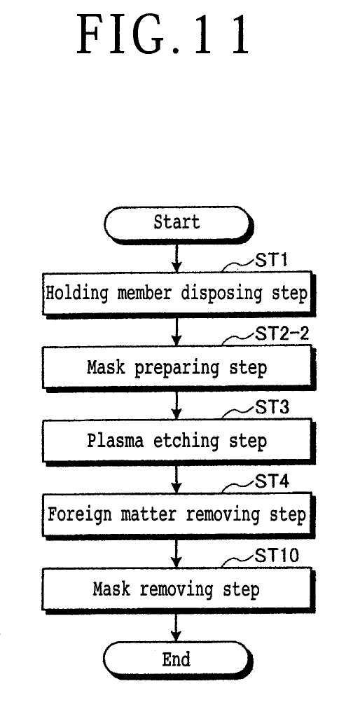

A processing method according to a second embodiment of the present invention will be described referring to the drawing. FIG. 11 is a flow chart depicting the flow of the processing method according to the second embodiment. In FIG. 11, the same parts as those in the first embodiment above are represented by the same symbols as used above, and descriptions of them will be omitted.

The processing method according to the second embodiment is the same as the processing method according to the first embodiment, except that the passivation layer 205 is not formed on the workpiece 200 to be processed, that a mask preparing step ST2-2 is different from the mask preparing step in the processing method according to the first embodiment, and that a mask removing step ST10 is performed after the foreign matter removing step ST4 is conducted.

In the mask preparing step ST2-2 of the processing method according to the second embodiment, a water-soluble resin composed of polyvinyl alcohol (PVA), polyvinylpyrrolidone (PVP) or the like is applied to the whole part of the front surface 203 of the workpiece 200, after which cutting processing or ablation processing of irradiation with a laser beam is applied to the streets 201, to expose the streets 201, thereby forming a mask. While the mask is formed from the water-soluble resin in the mask preparing step ST2-2 in the second embodiment, a mask may be prepared in the present invention by applying a resist which is a liquid becoming plasma-resistant when cured to the whole part of the front surface 203 of the workpiece 200, followed by exposure and development, to remove the resist present on the streets 201. Note that in applying the resist, for example, the workpiece 200 is held on a turntable rotatable about an axis, and the resist is supplied onto the front surface 203 while rotating the turntable about the axis.

The mask removing step ST10 of the processing method according to the second embodiment is a step of removing the mask after the foreign matter removing step ST4 is conducted. In the case where the mask is formed from a water-soluble resin, the mask removing step ST10 is carried out by supplying a cleaning liquid such as pure water to the surface of the mask. In the case where the mask is formed from a resist, the mask is removed by performing ashing. Note that in the case where the mask is formed from a resist and a resist stripping agent is used as the cleaning liquid in the foreign matter removing step ST4 in the second embodiment, the mask may be removed together with the coating 300 in the foreign matter removing step ST4, without carrying out the mask removing step ST10.

In the processing method according to the second embodiment, like in the first embodiment, the foreign matter removing step ST4 of removing the coating 300 as a foreign matter by use of the cleaning liquid 100 is performed after the plasma etching step ST3, and, therefore, the coating 300 can be removed from the devices 202. As a result, it is possible, by the processing method according to the second embodiment, to restrain defective mounting of the device 202 and breaking after the processing, such as breaking of wire.

### Third Embodiment

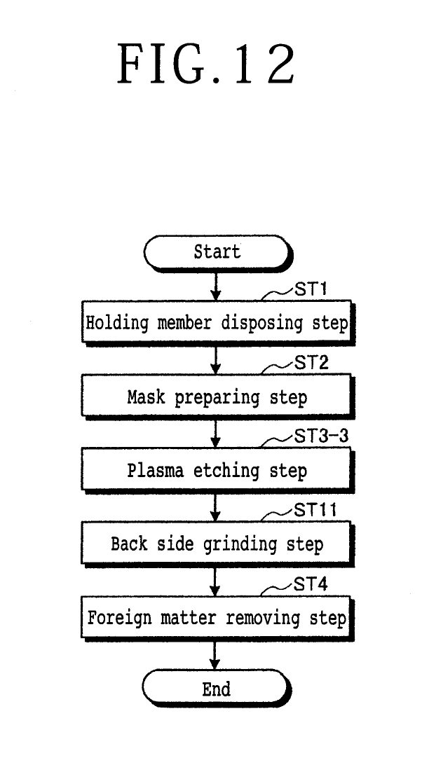

A processing method according to a third embodiment of the present invention will be described below referring to the drawing. FIG. 12 is a flow chart depicting the flow of the processing method according to the third embodiment. In FIG. 12, the same parts as those in the first embodiment above are represented by the same symbols as used above, and descriptions of them will be omitted.

The processing method according to the third embodiment is the same as the processing method according to the first embodiment, except that a plasma etching step ST3-3 is different from the plasma etching step of the processing method in the first embodiment, and that the foreign matter removing step ST4 is carried out after a back side grinding step ST11 is performed after the plasma etching step ST3-3 is conducted.

In the plasma etching step ST3-3 of the processing method according to the third embodiment, the grooves 220 are formed in the streets 201 in such a manner that the workpiece 200 is not divided into the individual devices 202 by the grooves 220 but that the depth of the grooves 220 is not less than a finished thickness of the devices 202. The back side grinding step ST11 is a step of grinding the back surface 208 of the workpiece 200 to expose the grooves 220 to the back surface 208 side, thereby dividing the workpiece 200 into the individual devices 202.

In performing the back side grinding step ST11, a protective member (not depicted) is attached to the front surface 203 of the workpiece 200, the adhesive tape 211 is peeled off the back surface 208, the front surface 203 side of the workpiece 200 is suction held onto a chuck table of a grinding apparatus (not depicted) through the protective member, a grindstone or grindstones are put in contact with the back surface 208 of the workpiece 200, and the chuck table and the grindstone or grindstones are rotated about respective axes. In the back side grinding step ST11, the back surface 208 of the workpiece 200 is ground to thin the workpiece 200 to its finished thickness. Since the depth of the grooves 220 is not less than the finished thickness, thinning the workpiece 200 to its finished thickness in the back side grinding step ST11 results in that the grooves 220 are exposed to the back surface 208 side, whereby the workpiece 200 is divided into the individual devices 202.

In the processing method according to the third embodiment, like in the first embodiment, the foreign matter removing step ST4 of removing the coating 300 by use of the cleaning liquid 100 is conducted after the plasma etching step ST3-3, and, therefore, the coating 300 can be removed from the devices 202. As a result, it is possible, by the processing method according to the third embodiment, to restrain defective mounting of the device 202 and breaking after the processing, such as breaking of wire.

In addition, in the processing method according to the third embodiment, the back side grinding step ST11 is performed after the plasma etching step ST3-3, and, therefore, the thickness of the devices 202 can be set to a desired finished thickness.

The present inventor has confirmed the effects of the aforementioned first and second embodiments. The results are set forth in Tables 1 and 2 below.

TABLE 1

| | Presence/absence of coating |
|---|---|
| Comparative Example 1 | present |
| Comparative Example 2 | present |
| Present Invention Product 1 | absent |
| Present Invention Product 2 | absent |
| Present Invention Product 3 | slightly present |
| Present Invention Product 4 | slightly present |

Table 1 depicts the results of confirmation of the effects of the foreign matter removing step ST4 of the processing methods according to the first and second embodiments. Specifically, the status in which the coating 300 was left, particularly, in the vicinity of the projecting electrodes 204 after the processing was confirmed by use of a scanning electron microscope (SEM) and an energy dispersive X-ray spectrometry (EDX). In Comparative Example 1 in Table 1, a processing method configured by eliminating the foreign matter removing step ST4 from the processing method according to the first embodiment depicted in FIG. 4 was carried out. In Comparative Example 2 in Table 1, a processing method configured by eliminating the foreign matter removing step ST4 from the processing method according to the second embodiment depicted in FIG. 11 was carried out.

In addition, Present Invention Products 1 and 2 in Table 1 are products obtained by using a fluorine-based cleaning liquid, particularly HFE (hydrofluoroether), as the cleaning liquid. Present Invention Products 3 and 4 are products obtained by using a resist stripping agent, particularly an organic solvent-based resist stripping agent, as the cleaning liquid 100. Present Invention Products 1 and 3 are products obtained by carrying out the processing method according to the first embodiment, and applying ultrasonic vibration to the cleaning liquid 100 in the foreign matter removing step ST4. Present Invention Products 2 and 4 are products obtained by carrying out the processing method according to the second embodiment, without applying ultrasonic vibration to the cleaning liquid 100 in the foreign matter removing step ST4.

In Comparative Examples 1 and 2, fluorine was detected, and it was verified that the coating 300 had been deposited. In Present Invention Products 1 and 2, fluorine was not detected, and it was verified that the coating 300 had been removed. In Present Invention Products 3 and 4, the amounts of fluorine detected were suppressed as compared to Comparative Examples 1 and 2, and it was verified that the amounts of the coating 300 left had successfully been suppressed. Accordingly, it is clearly seen from Table 1 that when the foreign matter removing step ST4 is carried out and a fluorine-based cleaning liquid, particularly HFE (hydrofluoroether), is used as the cleaning liquid 100, it is possible to remove the coating 300. Besides, it is clearly seen from Table 1 that when the foreign matter removing step ST4 is carried out and a resist stripping agent, particularly an organic solvent-based resist stripping agent, is used as the cleaning liquid 100, it is possible to suppress the amount of the coating 300.

TABLE 2

| | Dropping of device |
|---|---|
| Present Invention Product 5 | absent |
| Present Invention Product 6 | absent |
| Present Invention Product 7 | absent, though kind of adhesive tape |
| | is restricted |
| Present Invention Product 8 | absent, though kind of adhesive tape |
| | is restricted |

Table 2 depicts the results of confirmation of dropping of the device 202 from the adhesive tape 211 during the foreign matter removing step ST4 in the processing methods according to the first and second embodiments. Specifically, dropping of the workpiece 200 from each of various kinds of adhesive tapes used as the adhesive tape 211 was confirmed. The adhesive tapes 211 used in the confirmation depicted in Table 2 are adhesive tapes using PET, PO, or PVC to form the base material layer 213, using an acrylic or rubber-based resin to form the glue layer 214, and having various values of thickness.

In Present Invention Products 5 and 6 in Table 2, a fluorine-based cleaning liquid, particularly HFE (hydrofluoroether), was used as the cleaning liquid. In Present Invention Products 7 and 8, a resist stripping agent, particularly an organic solvent-based resist stripping agent, was used as the cleaning liquid 100. In Present Invention Products 5 and 7, ultrasonic vibration was applied to the cleaning liquid 100 in the foreign matter removing step ST4. In Present Invention Products 6 and 8, ultrasonic vibration was not applied to the cleaning liquid 100 in the foreign matter removing step ST4.

In Present Invention Products 5 and 6, the device 202 did not dropped from each of various kinds of adhesive tapes 211. Accordingly, it is clearly seen from Table 2 that when the foreign matter removing step ST4 is conducted and a fluorine-based cleaning liquid, particularly HFE (hydrofluoroether), is used as the cleaning liquid 100, it is possible to remove the coating 300, without lowering the adhesive force of the glue layer 214 in any of various kinds of adhesive tapes 211, and, hence, without dropping of the device 202 from any of the various kinds of adhesive tapes 211.

In Present Invention Products 7 and 8, the device 202 did not drop from any of specific kinds of adhesive tapes 211. Accordingly, it is clearly seen from Table 2 that when the foreign matter removing step ST4 is conducted and a resist stripping agent, particularly an organic solvent-based resist stripping agent, is used, it is possible to suppress the amount of the coating 300 left on the device 202, without lowering the adhesive force of the glue layer 214 in any of specific kinds of adhesive tapes 211, and, hence, without dropping of the device 202 from any of the specific kinds of adhesive tapes 211.

In addition, in Present Invention Products 5, 6, 7, and 8, dropping of the device 202 from the adhesive tape 211 did not occur when the adhesive tape 211 was one that includes a polymer having a high density and a high molecular weight. Accordingly, it has been made clear that the use of an adhesive tape 211 that includes a polymer having a high density and a high molecular weight is considered to be preferable because swelling with a chemical can be restrained.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A processing method for a workpiece which has a front surface formed with a device in each of regions partitioned by a plurality of intersecting streets, the device being provided with projecting electrodes, the processing method comprising:
a mask preparing step of preparing a mask that covers the devices on the front surface of the workpiece and exposes the streets;
a plasma etching step of repeating an operation of supplying plasmatized SF₆ through the mask to the workpiece in which the devices on the front surface are covered with the mask and which is accompanied by a holding member disposed on a back surface thereof, to form grooves, then supplying plasmatized C₄F₈ to the workpiece through the mask to deposit a coating on the workpiece, and thereafter supplying plasmatized SF₆ to the workpiece through the mask to remove the coating present at bottoms of the grooves, thereby etching the groove bottoms; and
a foreign matter removing step of cleaning the workpiece with a cleaning liquid, after the plasma etching step is conducted, to remove the coating produced in the plasma etching step.

2. The processing method for a workpiece according to claim 1, further comprising:
a holding member disposing step of disposing the holding member on the back surface of the workpiece, before conducting the plasma etching step.

3. The processing method for a workpiece according to claim 1, wherein the foreign matter removing step is carried out by immersing the workpiece in the cleaning liquid.

4. The processing method for a workpiece according to claim 3,
wherein the holding member includes a tape including a base material layer and a glue layer disposed on the base material layer, and an annular frame to which an outer peripheral edge of the tape is attached, and
in the foreign matter removing step, the workpiece is immersed in the cleaning liquid together with the tape adhered to the back surface of the workpiece and the annular frame.

5. The processing method for a workpiece according to claim 3, wherein the foreign matter removing step is carried out by heating the cleaning liquid to a temperature of not lower than normal temperature and applying ultrasonic vibration to the cleaning liquid.
